(19) United States
(12) Patent Application Publication
(10) Pub. No.: US 2007/0243669 A1
(43) Pub. Date: Oct. 18, 2007

(54) Method for manufacturing solid-state image pickup element and solid-state image pickup element

(75) Inventors: Hisashi Suzuki, Minami-Ashigara-shi (JP); Hideyasu Hanaoka, Sendai-shi (JP); Tsuyoshi Makita, Sendai-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Minato-ku (JP)

(21) Appl. No.: 11/785,480

(22) Filed: Apr. 18, 2007

(30) Foreign Application Priority Data
Apr. 18, 2006 (JP) 2006-114715

(51) Int. Cl. H01L 21/8232

(52) U.S. Cl. 438/142

(57) ABSTRACT

The present invention provides a method for manufacturing a solid-state image pickup element in which an intralayer lens is formed above a solid-state image pickup element by: a first step of forming a film using an intralayer lens forming material; a second step of reducing an aspect ratio which is obtained by dividing a depth of concave portion after undergoing the first step by a spacing between convex portions, by either performing etchback after coating the film with a resist or performing sputter etching; and a third step of forming a new film on the film with the reduced aspect ratio using the intralayer lens forming material.

### BACKGROUND OF THE INVENTION

1. Field of the Invention

The present invention relates to a method for manufacturing a solid-state image pickup element in which an interlayer lens is formed and a solid-state image pickup element in which an interlayer lens is formed.

2. Description of the Related Art

A CCD (Charge Coupled Device) used in a digital camera or the like is manufactured by forming a large number of photodiodes, transfer electrodes, and the like in a semiconductor substrate and further forming an intralayer lens, a color filter, a microlens, and the like above the previously formed components.

FIG. 1 shows the configuration of a solid-state image pickup element. FIG. 1 is an enlarged sectional view of some of pixels of the solid-state image pickup element. In a solid-state image pickup element 1, a photodiode 3 and a transfer channel 4 are formed in the surface of a semiconductor substrate 2 of, e.g., silicon, and a transfer electrode 5 covered with a light-shielding film of, e.g., tungsten is formed on the transfer channel 4.

A BPSG (borophospho silicate glass) film 6 serving as an interlayer insulating film is formed on the transfer electrode 5. An intralayer lens 7 of SiN (silicon nitride) is formed on the BPSG film 6, and a color filter 8 and a microlens 9 are formed above the intralayer lens 7.

In the manufacturing process of the solid-state image pickup element 1 with this configuration, the BPSG film 6 is formed by atmospheric pressure CVD (Chemical Vapor Deposition), as shown in FIG. 5A. After the formation of the BPSG film 6, the BPSG film 6 is reflowed, and a concave lens-shaped portion is formed, as shown in FIG. 5B. After the formation of the concave lens-shaped portion, a film is formed using SiN, which has a high refractive index and is highly transparent, as an intralayer lens material, as shown in FIG. 5C.

However, since plasma CVD is generally used in the formation of a SiN film, which requires a low temperature (500° C. or less), a SiN film formed thereby has poor coverage. Additionally, the aspect ratio of an underlying layer concave portion shown in FIG. 6 increases along with the recent miniaturization of pixels of a solid-state image pickup element.

Because of this, a void B is likely to be formed in the central part of the intralayer lens 7, as shown in FIG. 5D. Diffuse reflection caused by the void impairs the efficiency of focusing light on a light-receiving portion and reduces the sensitivity.

To cope with this problem, there has been proposed a method for manufacturing a solid-state image pickup element in which a mist of a solution having an optically transparent material to be buried in an optical waveguide portion dissolved therein is supplied to a film formation surface to form a liquid film, and the liquid film is burned, thereby burying the liquid film in the optical waveguide portion without forming a void (see, e.g., Japanese Patent Application Laid-Open No. 2003-282851).

There has also been proposed a method for manufacturing a solid-state image pickup element which has an opening portion formed to have a stepped shape and the improved ability of a transparent film to be buried in an optical waveguide portion (see, e.g., Japanese Patent Application Laid-Open No. 2003-224249).

However, the method for manufacturing a solid-state image pickup element described in Japanese Patent Application Laid-Open No. 2003-282851 requires another new expensive apparatus such as a manufacturing apparatus for dissolving the optically transparent material in the solution and turning the solution into a mist. It is also necessary to form the film in a plurality of steps and add a heat treatment step for burning. This increases the number of steps and requires a longer time. Additionally, it is difficult to acquire desired optical properties (e.g., a refractive index and an attenuation coefficient).

In the method for manufacturing a solid-state image pickup element described in Japanese Patent Application Laid-Open No. 2003-224249, the stepped shape of the opening portion increases the number of steps and reduces throughput. Also, the opening portion with the stepped shape cannot acquire a sufficient light-focusing property.

### SUMMARY OF THE INVENTION

The present invention has been made in consideration of the above-described circumstances, and has as its object to provide a method for manufacturing a solid-state image pickup element intended to manufacture a solid-state image pickup element which is free from voids, has improved light-focusing efficiency, and is highly sensitive at a low cost even if the aspect ratio of an underlying layer concave portion is high and a solid-state image pickup element which has improved light-focusing efficiency and is highly sensitive.

In order to achieve the object, according to a first aspect of the present invention, an intralayer lens is formed above a solid-state image pickup element by a first step of forming a film using an intralayer lens forming material, a second step of reducing an aspect ratio which is obtained by dividing a depth of concave portion after undergoing the first step by a spacing between convex portions, by either performing etchback after coating the film with a resist or performing sputter etching, and a third step of forming a new film on the film with the reduced aspect ratio using the intralayer lens forming material.

According to the first aspect, a photodiode, a transfer channel, a transfer electrode, and the like are formed at the surface of a semiconductor substrate, and a BPSG film is formed on the components and reflowed. As a first step, a film is formed on the BPSG film with a concave lens-shaped portion formed by the reflow, using the intralayer lens forming material, which has a high refractive index and is highly transparent.

As a second step, for the film formed using the intralayer lens forming material, the aspect ratio is reduced by one of a process of coating the film formed using the intralayer lens forming material with the resist and performing etchback and planarization and a process of selectively etching an angulated portion by sputter etching using Ar (argon). As a third step, a new film is formed on the film with the reduced aspect ratio using the intralayer lens forming material.

This prevents formation of a void in the new film formed on the film with the reduced aspect ratio and makes it possible to manufacture a solid-state image pickup element which is free from diffuse reflection of incident light, has improved light-focusing efficiency, and is highly sensitive without introducing a new apparatus and only by adding simple steps.

According to a second aspect of the present invention, in the first aspect, in the first step, a solid-state image pickup element component is formed at a surface of a semiconductor substrate, a BPSG film is formed on the solid-state image pickup element component, and the film is formed on the BPSG film having a concave-convex surface whose aspect ratio obtained by dividing a depth of a concave portion formed by reflowing the BPSG film by a spacing between convex portions is not less than 0.3, using the intralayer lens forming material.

According to the second aspect, a photodiode, a transfer channel, a transfer electrode, and the like serving as the solid-state image pickup element components are formed at the surface of the semiconductor substrate, and the BPSG film is formed on the solid-state image pickup element components and reflowed. The first step of forming the film using the intralayer lens forming material is performed for the BPSG film, whose aspect ratio obtained by dividing the depth of the concave portion formed by the reflow by the spacing between the convex portions has a value of not less than 0.3.

According to a third aspect of the present invention, in the first or second aspects, the intralayer lens forming material is one of silicon nitride, titanium oxide, zirconium oxide, aluminum oxide, and tantalum oxide, and a refractive index within a visible range is not less than 1.6.

According to the third aspect, the intralayer lens is formed on the solid-state image sensor using the intralayer lens forming material, which has a high refractive index and is highly transparent. This makes it possible to manufacture a solid-state image pickup element which is highly sensitive.

According to a fourth aspect of the present invention, in any one of the first to third aspects, the aspect ratio after the second step, which is obtained by dividing the depth of the concave portion by the spacing between the convex portions, has a value of less than 0.3.

According to the fourth aspect, no void is formed in the film newly formed using the intralayer lens material in the third step, and it is possible to manufacture a solid-state image pickup element which is free from diffuse reflection of incident light, has improved light-focusing efficiency, and is highly sensitive.

According to a fifth aspect of the present invention, in any one of the first to fourth aspects, after performing the first to third steps, the second and third steps are performed a plurality of times, thereby forming a plurality of the films.

According to the fifth aspect, repetition of the second and third steps makes it possible to reliably suppress a void which cannot be suppressed by performing the second and third steps once due to the large aspect ratio of an underlying layer.

Since the intralayer lens with a multilayered structure, which is free from voids, is formed, and the plurality of the films have different refractive indexes, the formed intralayer lens serves as a graded index lens, and a solid-state image pickup element is manufactured which has high light-focusing efficiency and is highly sensitive.

According to a sixth aspect of the present invention, in the fifth aspect, one of the plurality of the films which is formed in a step is higher in refractive index than one which is formed in a step immediately preceding the step by 0.05 to 0.5.

According to the sixth aspect, the intralayer lens with a multilayered structure formed by stacking the plurality of the films serves as a graded index lens, and it is possible to manufacture a solid-state image pickup element which has high light-focusing efficiency and is highly sensitive.

According to a seventh aspect of the present invention, a film is formed using an intralayer lens forming material, a process is repeated of reducing an aspect ratio obtained by dividing a depth of a concave portion of the formed film by a spacing between convex portions by one of a process of coating the film with a resist and performing etchback and a process of performing sputter etching and then forming a new film on the film with the reduced aspect ratio using the intralayer lens forming material, thereby forming an intralayer lens above a solid-state image sensor using a plurality of the films.

According to the seventh aspect, a BPSG film is formed on a semiconductor substrate having a photodiode and the like and reflowed, and a new film is formed on the BPSG film with a concave lens-shaped portion, using the intralayer lens forming material.

The aspect ratio of the formed film is reduced by one of a process of coating the film with the resist and performing etchback and planarization and a process of selectively etching an angulated portion by sputter etching using Ar (argon). After the aspect ratio is reduced, a new film is further formed on the new film formed, using the intralayer lens forming material.

This prevents formation of a void in the new film formed on the film with the reduced aspect ratio and makes it possible to obtain a solid-state image pickup element which is free from diffuse reflection of incident light, has improved light-focusing efficiency, and is highly sensitive.

As has been explained above, according to a method for manufacturing a solid-state image pickup element and a solid-state image pickup element of the present invention, a new film is formed on a film with a reduced aspect ratio, and formation of a void is prevented. This makes it possible to manufacture a solid-state image pickup element which is free from diffuse reflection of incident light, has improved light-focusing efficiency, and is highly sensitive without introducing a new apparatus and only by adding simple steps.

### BRIEF DESCRIPTION OF THE DRAWINGS

FIG. 1 is an enlarged sectional view of a part of a solid-state image pickup element according to the present invention;

FIG. 2 shows sectional views of a method for manufacturing a solid-state image pickup element;

FIG. 3 shows sectional views of a method for manufacturing a solid-state image pickup element according to another embodiment;

FIG. 4 is a sectional view of a solid-state image pickup element in which an intralayer lens with a multilayered structure is formed;

FIGS. 5A, 5B, 5C and 5D show sectional views of a conventional method for manufacturing a solid-state image pickup element; and

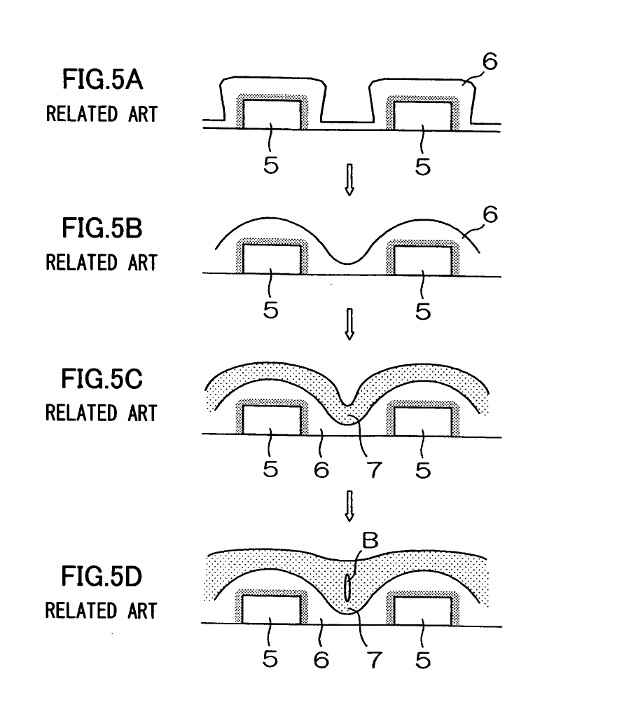

FIG. 6 is a sectional view representing the definition of an aspect ratio.

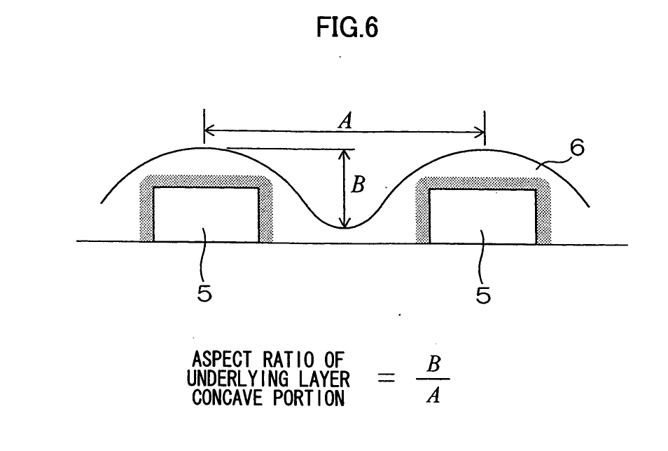

### DETAILED DESCRIPTION OF THE PREFERRED EMBODIMENTS

Preferred embodiments of a method for manufacturing a solid-state image pickup element and a solid-state image pickup element according to the present invention will be explained in detail below with reference to the accompanying drawings.

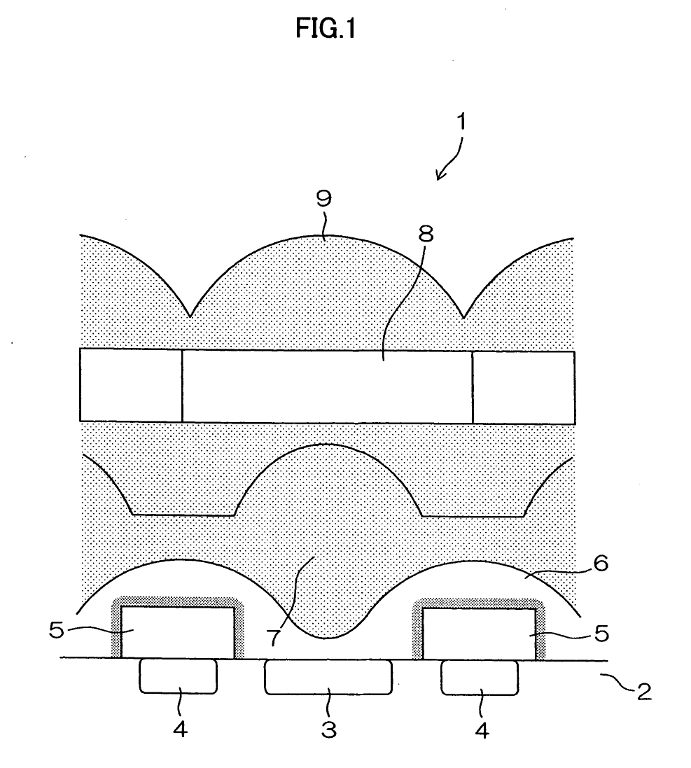

The configuration of a solid-state image pickup element according to the present invention will be explained first. In a solid-state image pickup element 1 shown in FIG. 1, an n-type photodiode 3 and an n-type transfer channel 4 serving as solid-state image pickup element components are formed in the surface of a semiconductor substrate 2 obtained by forming a p-type well layer on an n-type substrate. A transfer electrode 5 is formed above the transfer channel 4 through an insulating film made of, e.g., silicon oxide.

The transfer electrode 5 is formed of, e.g., polysilicon and covered with a light-shielding film made of W (tungsten) which has an opening portion on the photodiode 3. A BPSG film 6 which is formed by atmospheric pressure CVD and reflowed is formed on the transfer electrode 5 covered with the light-shielding film.

The BPSG film 6 has a concave lens-shaped portion in which an intralayer lens 7 is formed by plasma CVD using SiN, which has a high refractive index and is highly transparent.

A color filter 8 of three primary colors, red (R), green (G), and blue (B), is formed above the intralayer lens 7. A microlens 9 is formed on the color filter 8 using a photoresist material.

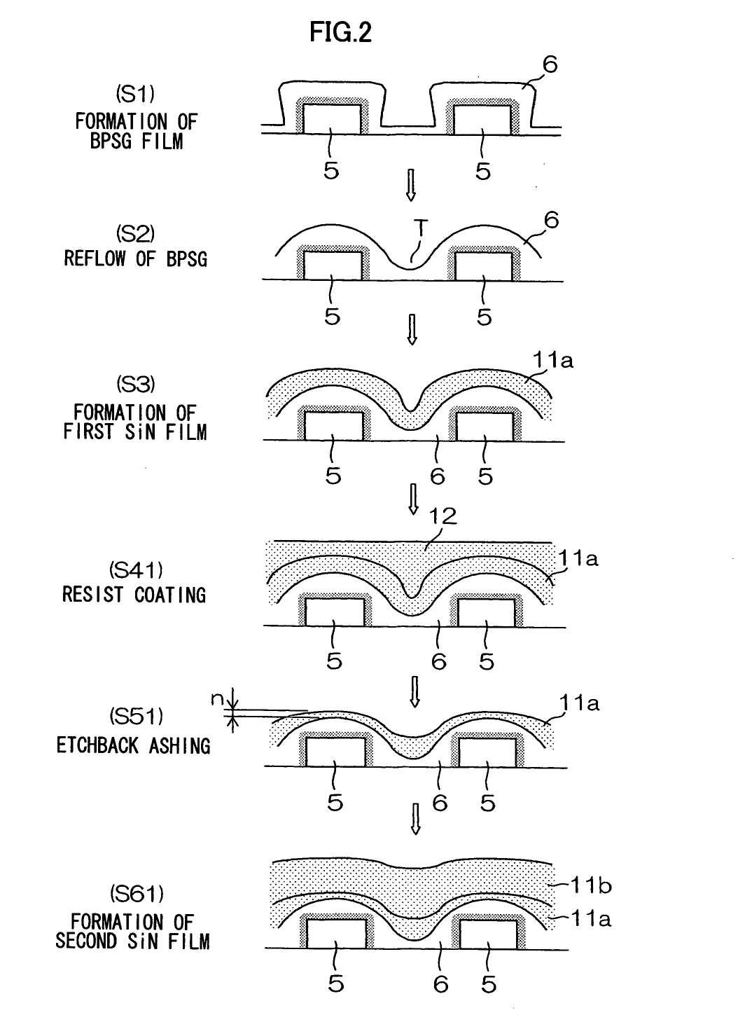

A method for manufacturing a solid-state image pickup element according to the present invention will be explained next. FIG. 2 shows sectional views of a method for manufacturing an intralayer lens of a solid-state image pickup element.

In the method for manufacturing a solid-state image pickup element according to the present invention, the BPSG film 6 is first formed on the transfer electrode 5 formed on the semiconductor substrate 2 shown in FIG. 1 by atmospheric pressure CVD (step S1). The BPSG film 6 is formed to have a thickness of 100 to 700 nm, preferably 200 to 300 nm.

After the formation, the BPSG film 6 is reflowed to have a concave intralayer lens-shaped portion T (step S2). At this time, the aspect ratio of the concave intralayer lens-shaped portion T is about 0.4.

As a first step, a film 11a of SiN, which is suitable as an intralayer lens material, is formed on the BPSG film 6 with the concave intralayer lens-shaped portion T by a single wafer plasma CVD apparatus (step S3).

The SiN film 11a is formed to have a thickness of 200 to 700 nm, preferably 400 to 500 nm. The operating conditions for the single wafer plasma CVD apparatus are as follows: pressure, 399 to 798 Pa, preferably 532 to 665 Pa; RF power, 400 to 1,000 W, preferably 500 to 600 W; RF frequency, 13.56 MHz; electrode spacing, 10 to 15.3 mm, preferably 11.4 to 12.7 mm; susceptor temperature, 300 to 400° C., preferably 350 to 400° C.; and flow rate (depending on the type of gas), 60 to 200 sccm (in the case of SiH₄), preferably 120 to 150 sccm, 150 to 300 sccm (in the case of NH₃), preferably 180 to 250 sccm, or 3,000 to 6,000 sccm (in the case of N₂), preferably 4,000 to 5,000 sccm.

After the SiN film 11a is formed, a resist film 12 is formed on the SiN film 11a (step S41).

The resist film 12 is formed by coating the SiN film 11a with an acrylic negative resist using a spin coater and drying the resist. After the drying, the resist film 12 is subjected to overall exposure using an i-line stepper, development, and post-baking.

After the formation of the resist film 12, as a second step, etchback is performed by an RIE (Reactive Ion Etching) apparatus (step S51).

In the etchback, an etching ratio is adjusted according to a gas flow rate, and etching is performed until the thickness of a thinnest portion n of the SiN film 11a above the transfer electrode 5 is reduced to 200 nm to make the aspect ratio equal to or less than 0.3. In this embodiment, the etching is performed such that the aspect ratio becomes equal to or less than 0.25.

The operating conditions for the RIE apparatus are as follows: pressure, 13.3 to 266 Pa, preferably 53.2 to 93.1 Pa; RF power, 700 to 1,000 W, preferably 800 to 900 W; RF frequency, 380 KHz; flow rate (depending on the type of gas), 60 to 100 sccm (in the case of CF₄), preferably 70 to 80 sccm, 100 to 140 sccm (in the case of Ar), preferably 120 to 130 sccm, or 60 to 100 sccm (in the case of O₂), preferably 80 to 90 sccm; and etching selectivity of resist with respect to SiN, 1 to 4, preferably 1.5 to 2.

After the etchback, the remaining resist is removed by an asher, and as a third step, an SiN film 11b is formed by the single wafer plasma CVD apparatus (step S61).

This prevents formation of a void in the new SiN film 11b formed on the SiN film 11a with the reduced aspect ratio. In the above-described manner, a solid-state image pickup element is manufactured which is free from diffuse reflection of incident light caused by a void, has improved light-focusing efficiency, and is highly sensitive.

Note that it is experimentally confirmed that the solid-state image pickup element of this embodiment is higher in the efficiency of focusing light on a solid-state image sensor (sensitivity) than one manufactured by a conventional process by about 15%.

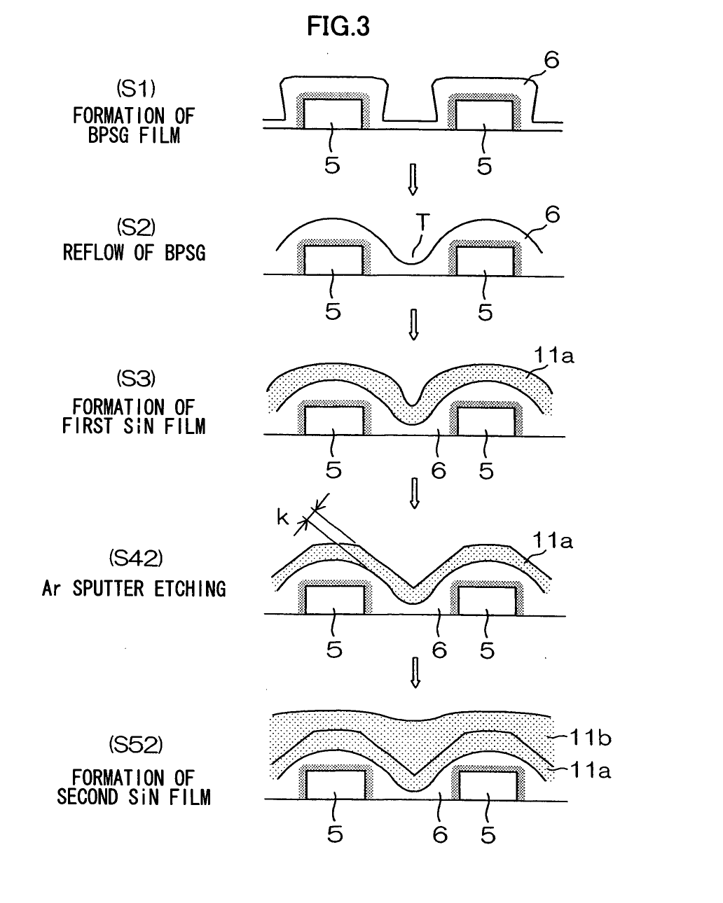

Another embodiment of a method for manufacturing a solid-state image pickup element according to the present invention will be explained next. FIG. 3 shows sectional views of a method for manufacturing a solid-state image pickup element according to this embodiment.

In this embodiment as well, a BPSG film 6 is formed on a transfer electrode 5 by atmospheric pressure CVD (step S1).

After the formation, the BPSG film 6 is reflowed to have a concave intralayer lens-shaped portion T (step S2).

As a first step, an SiN film 11a is formed on the BPSG film 6 with the concave intralayer lens-shaped portion T by a single wafer plasma CVD apparatus (step S3).

At this time, the aspect ratio of the concave intralayer lens-shaped portion T, in which the SiN film 11a is formed, is about 0.4, as in the embodiment explained above. The thickness of the BPSG film 6, the thickness of the SiN film 11a, the operating conditions for the single wafer plasma CVD apparatus, and the like are the same as those in the embodiment.

After the formation of the SiN film 11a, as a second step, the SiN film 11a is subjected to sputter etching using Ar by an ECR (Electron Cyclotron Resonance) apparatus (step S42).

In the sputter etching, only an angulated portion is selectively etched until the thickness of a thinnest portion k of the SiN film 11a on the BPSG film 6 is reduced to 200 nm to make the aspect ratio equal to or less than 0.3. In this embodiment, the etching is performed such that the aspect ratio becomes equal to or less than 0.23.

The operating conditions for the ECR apparatus are as follows: pressure, 0.133 to 1.33 Pa, preferably 0.399 to 0.798 Pa; microwave power, 1,000 to 2,000 W, preferably 1,400 to 1,500 W; microwave power frequency, 2.45 GHz; bias RF power, 700 to 1,500 W, preferably 900 to 1,000 W; bias RF frequency, 400 KHz; and Ar gas flow rate, 300 to 700 sccm, preferably 400 to 500 sccm.

After the sputter etching, as a third step, a SiN film 11b is formed by the single wafer plasma CVD apparatus (step S52).

This prevents formation of a void in the new SiN film 11b formed on the SiN film 11a with the reduced aspect ratio. In the above-described manner, a solid-state image pickup element is manufactured which is free from diffuse reflection of incident light caused by a void, has improved light-focusing efficiency, and is highly sensitive.

Note that it is experimentally confirmed that the solid-state image pickup element of this embodiment is higher in the efficiency of focusing light on a solid-state image pickup element (sensitivity) than one manufactured by a conventional process by about 18%.

As has been explained above, according to a method for manufacturing a solid-state image pickup element and a solid-state image pickup element according to the present invention, a new film is formed on the film of an intralayer lens with a reduced aspect ratio, and no void is formed in the central part of the intralayer lens. Also, since a solid-state image pickup element which has improved light-focusing efficiency and is highly sensitive can be manufactured without introducing a new apparatus and only by adding simple steps, it is possible to manufacture such a solid-state image pickup element at a low cost.

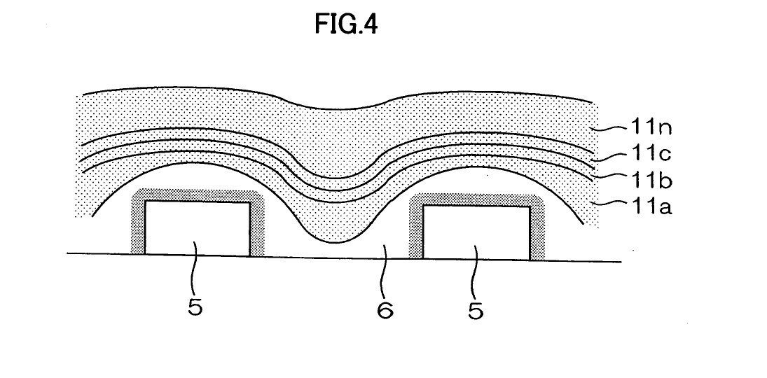

Note that although in this embodiment, only the two SiN films 11a and 11b are used as SiN films, the present invention is not limited to this. Even if a plurality of SiN films 11a, 11b, 11c, . . . , 11n are formed and stacked, as shown in FIG. 4, the SiN films can be preferably used in the present invention.

At this time, one of the formed SiN films 11a, 11b, 11c, . . . , 11n is higher in refractive index than an immediately preceding one on which the one is formed by 0.05 to 0.5. Accordingly, an intralayer lens with a multilayered structure which is free from voids and whose refractive index varies by site is formed, and the formed intralayer lens serves as a graded index lens. In the above-described manner, a solid-state image pickup element is manufactured which has high light-focusing efficiency and is highly sensitive.

In this embodiment, SiN (silicon nitride) is used as an intralayer lens forming material. The present invention, however, is not limited to this. TiO₂ (titanium oxide), ZrO₂ (zirconium oxide), Al₂O₃ (aluminum oxide), or Ta₂O₅ (tantalum oxide), whose refractive index within a visible range is equal to or more than 1.6 can be preferably used in the present invention.

What is claimed is:

1. A method for manufacturing a solid-state image pickup element in which an intralayer lens is formed above a solid-state image pickup element by:
a first step of forming a film using an intralayer lens forming material;
a second step of reducing an aspect ratio which is obtained by dividing a depth of concave portion after undergoing the first step by a spacing between convex portions, by either performing etchback after coating the film with a resist or performing sputter etching; and
a third step of forming a new film on the film with the reduced aspect ratio using the intralayer lens forming material.

2. The method for manufacturing a solid-state image pickup element according to claim 1, wherein
in the first step, a solid-state image pickup element component is formed at a surface of a semiconductor substrate, a BPSG film is formed on the solid-state image pickup element component, and the film is formed on the BPSG film having a concave-convex surface whose aspect ratio obtained by dividing a depth of a concave portion formed by reflowing the BPSG film by a spacing between convex portions is not less than 0.3, using the intralayer lens forming material.

3. The method for manufacturing a solid-state image pickup element according to claim 1, wherein
the intralayer lens forming material is one of silicon nitride, titanium oxide, zirconium oxide, aluminum oxide, and tantalum oxide, and a refractive index within a visible range is not less than 1.6.

4. The method for manufacturing a solid-state image pickup element according to claim 2, wherein
the intralayer lens forming material is one of silicon nitride, titanium oxide, zirconium oxide, aluminum oxide, and tantalum oxide, and a refractive index within a visible range is not less than 1.6.

5. The method for manufacturing a solid-state image pickup element according to claim 1, wherein
the aspect ratio after the second step, which is obtained by dividing the depth of the concave portion by the spacing between the convex portions, has a value of less than 0.3.

6. The method for manufacturing a solid-state image pickup element according to claim 2, wherein
the aspect ratio after the second step, which is obtained by dividing the depth of the concave portion by the spacing between the convex portions, has a value of less than 0.3.

7. The method for manufacturing a solid-state image pickup element according to claim 3, wherein
the aspect ratio after the second step, which is obtained by dividing the depth of the concave portion by the spacing between the convex portions, has a value of less than 0.3.

8. The method for manufacturing a solid-state image pickup element according to claim 1, wherein
after performing the first to third steps, the second and third steps are performed a plurality of times, thereby forming a plurality of the films.

9. The method for manufacturing a solid-state image pickup element according to claim 2, wherein
after performing the first to third steps, the second and third steps are performed a plurality of times, thereby forming a plurality of the films.

10. The method for manufacturing a solid-state image pickup element according to claim 3, wherein
after performing the first to third steps, the second and third steps are performed a plurality of times, thereby forming a plurality of the films.

11. The method for manufacturing a solid-state image pickup element according to claim 5, wherein
after performing the first to third steps, the second and third steps are performed a plurality of times, thereby forming a plurality of the films.

12. The method for manufacturing a solid-state image pickup element according to claim 8, wherein
one of the plurality of the films which is formed in a step is higher in refractive index than one which is formed in a step immediately preceding the step by 0.05 to 0.5.

13. The method for manufacturing a solid-state image pickup element according to claim 9, wherein
one of the plurality of the films which is formed in a step is higher in refractive index than one which is formed in a step immediately preceding the step by 0.05 to 0.5.

14. The method for manufacturing a solid-state image pickup element according to claim 10, wherein
one of the plurality of the films which is formed in a step is higher in refractive index than one which is formed in a step immediately preceding the step by 0.05 to 0.5.

15. The method for manufacturing a solid-state image pickup element according to claim 11, wherein
one of the plurality of the films which is formed in a step is higher in refractive index than one which is formed in a step immediately preceding the step by 0.05 to 0.5.

16. A solid-state image pickup element, wherein
a film is formed using an intralayer lens forming material, and
an intralayer lens is formed on a solid-state image pickup element with using a plurality of films which are formed by repeating a process of reducing an aspect ratio which is obtained by dividing a depth of a concave portion of the formed film by a spacing between convex portions, by either performing etchback after coating the film with a resist or performing sputter etching, and then forming a new film on the film with the reduced aspect ratio using the intralayer lens forming material.
